(19) United States
(12) Patent Application Publication
(10) Pub. No.: US 2013/0177765 A1
(43) Pub. Date: Jul. 11, 2013

(54) High-Rigidity Electromagnetic Shielding Composition and Molded Articles Thereof

(71) Applicant: CHEIL INDUSTRIES INC., Gumi-si (KR)

(72) Inventors: Yoon Sook LIM, Uiwang-si (KR); Kang Yeol PARK, Uiwang-si (KR); Chan Gyun SHIN, Uiwang-si (KR); Jee Kwon PARK, Uiwang-si (KR); Doo Young KIM, Uiwang-si (KR)

(73) Assignee: CHEIL INDUSTRIES INC., Gumi-si (KR)

(21) Appl. No.: 13/775,300

(22) Filed: Feb. 25, 2013

Related U.S. Application Data
(63) Continuation-in-part of application No. PCT/KR2010/009244, filed on Dec. 23, 2010.

(30) Foreign Application Priority Data
Aug. 26, 2010 (KR) 10-2010-0082973
Dec. 16, 2010 (KR) 10-2010-0129506

(51) Int. Cl. H05K 9/00; B32B 5/16

(52) U.S. Cl. CPC H05K 9/009; B32B 5/16
USPC 428/407; 252/478

(57) ABSTRACT

A high-rigidity electromagnetic shielding composition includes: (A) about 10 to about 34 wt % of polyamide resin including an aromatic moiety in the backbone structure; (B) about 65 to about 85 wt % of carbon fiber; and (C) about 1 to about 20 wt % of metallic filler. The composition can have high modulus, electromagnetic shielding effects, and high surface conductance, and can thus be used to replace frames, brackets and the like for electronic devices.

### CROSS-REFERENCE TO RELATED APPLICATIONS

This application is a continuation-in-part of International Application No. PCT/KR2010/009244, filed Dec. 23, 2010, pending, which designates the U.S., published as WO 2012/026652, and is incorporated herein by reference in its entirety, and claims priority therefrom under 35 USC Section 120. This application also claims priority under 35 USC Section 119 to and the benefit of Korean Patent Application No. 10-2010-0082973 filed Aug. 26, 2010, and Korean Patent Application No. 10-2010-0129506 filed Dec. 16, 2010, the entire disclosure of each of which is incorporated herein by reference.

### FIELD OF THE INVENTION

The present invention relates to a high-rigidity electromagnetic shielding composition and molded articles thereof.

### BACKGROUND OF THE INVENTION

Electromagnetic wave is a noise phenomenon caused by electrostatic discharge, and is known not only to cause noise and malfunction in surrounding components or devices but also to have harmful effects on the human body. Recently, the possibility of a user being exposed to electromagnetic radiation is rapidly increasing due to increased use of electric/electronic products having high efficiency, high power consumption and high integration, and regulations on electromagnetic radiation have been tightened in many countries.

Conventionally, methods for shielding electromagnetic waves may include the use of metallic materials. For example, brackets used in portable display products, such as mobile phones, laptop computers, PDAs, and other mobile items act as a frame to protect LCDs and shield electromagnetic waves, and thus require high rigidity and EMI shielding properties. Commonly used materials for brackets, frames and the like include metallic materials such as magnesium, aluminum, stainless steel, and the like. However, although these metallic materials can shield electromagnetic waves effectively, they are generally produced by die-casting and thus have disadvantages such as high manufacturing costs and high defect ratios.

Accordingly, replacing the metallic materials with thermoplastic materials having easy formability, excellent accuracy, excellent economic feasibility and productivity as compared to the metallic materials has been suggested.

Currently developed resins to replace metals have a modulus of 20 GPa or less and electromagnetic shielding effect of 30 dB (@1 GHz), and thus have much poorer rigidity and EMI shielding properties than metals. In order to improve modulus, a method of increasing the fiber content in the resin has been proposed. However, resins having a high content of fiber are not applicable in practice due to low impact strength, low flowability and poor processability, and have high surface resistance and too low conductivity to be used as materials for electronic devices.

For example, when polyamide resins are used as base resins, various properties of the final products can be easily deteriorated due to low dimensional stability and high absorption rate, and it can be difficult to provide high filler loading using a low flow base resin. Some products including 50% or more of carbon fibers can have high modulus and electromagnetic shielding effects of 30 dB or more. The carbon fibers, however, are not sufficient to replace metals, and such materials can be difficult to process. Furthermore, these materials can have too low conductivity to be used in electronic devices. For example, when the carbon fibers are used in a composition for a bracket of a general mobile phone, problems such as degradation in both grounding performance and antenna performance can occur.

To solve such problems, high-rigidity resins including a conductive plating can be used. The conductive plating, however can reduce surface resistance and can increase costs due to plating and subsequent processing, and can exhibit surface peeling upon long term use.

Therefore, there is a need for a new material which exhibits good flowability, impact strength and rigidity, and excellent conductivity and shielding properties to replace existing magnesium materials.

### SUMMARY OF THE INVENTION

The present invention can provide a high-rigidity electromagnetic shielding composition that can have excellent mechanical strength. The high-rigidity electromagnetic shielding composition can also have remarkable conductivity and low surface resistance and thus excellent electromagnetic interference (EMI) shielding properties, and accordingly can be suitable for EMI shielding. The high-rigidity electromagnetic shielding composition can further have excellent flowability and moldability, and thus excellent processability. Further, the high-rigidity electromagnetic shielding composition does not require post-processing steps, and can thus provide excellent economic feasibility and productivity. In addition, the high-rigidity electromagnetic shielding composition can have excellent dimensional stability. Accordingly the high-rigidity electromagnetic shielding composition is capable of replacing existing magnesium materials.

The present invention also provides molded articles formed of the high-rigidity electromagnetic shielding composition.

The technical problems which the present invention addresses are not limited to the aforementioned technical problems, and other technical problems can be clearly understood by those skilled in the art from the disclosure below.

The present invention provides a high-rigidity electromagnetic shielding composition which includes (A) about 10 wt % to about 34 wt % of a polyamide resin including an aromatic moiety in the backbone; (B) about 65 wt % to about 85 wt % of carbon fibers; and (C) about 1 wt % to about 20 wt % of a metallic filler.

In one embodiment, the (A) polyamide resin may include wholly aromatic polyamide, semi-aromatic polyamide, or a combination thereof.

The semi-aromatic polyamide may be a polymer of an aromatic diamine and an aliphatic dicarboxylic acid.

In one embodiment, the semi-aromatic polyamide may be represented by Formula 1:

H—[—NHCH₂—Ar—CH₂NHCO—R—COₙOH [Formula 1]

wherein Ar is an aromatic moiety, R is C₄ to C₂₀ alkylene, and n is an integer ranging from 50 to 500.

In one embodiment, the (B) carbon fiber may include a bundle of carbon fibers.

In one embodiment, the (C) metallic filler may include metal powders, metal beads, metal fibers, metal flakes, metal-coated particles, metal-coated fibers, and the like. These may be used alone or in combination of two or more thereof.

The (C) metallic filler may include aluminum, stainless, iron, chromium, nickel, black nickel, copper, silver, gold, platinum, palladium, tin, cobalt, and alloys thereof. These may be used alone or in combination of two or more thereof.

The composition may further include carbon nanotubes in an amount of greater than 0 parts by weight to about 20 parts by weight based on about 100 parts by weight of components (A)+(B)+(C).

The composition may further include metal-coated graphite. The metal-coated graphite may have a particle shape, a fiber shape, a flake shape, an amorphous shape, or a combination thereof.

The metal-coated graphite may have an average particle diameter of about 10 μm to about 200 μm.

In one embodiment, the metal may include aluminum, stainless, iron, chromium, nickel, black nickel, copper, silver, gold, platinum, palladium, tin, cobalt, an alloy thereof, or a combination thereof.

In one embodiment, the composition may further include one or more additives. Examples of the additives include flame retardants, plasticizers, coupling agents, heat stabilizers, light stabilizers, inorganic fillers, mold release agents, dispersing agents, anti-dripping agents, weather proof stabilizers, and the like. These may be used alone or in combination of two or more thereof.

In one embodiment, the composition may have a tensile strength of about 40 GPa or more as measured in accordance with ASTM D638 using a 3.2 mm thick specimen, a flexural modulus of about 40 GPa or more as measured in accordance with ASTM D790 using a 6.4 mm thick specimen, a shielding effect of about 50 dB or more as measured in accordance with EMI D790 using a 1 mm thick specimen at 1 GHz, a volume resistance of about 0.2 Ω·cm or less as measured in accordance with a 4-point probe method using a 1 mm thick specimen, and/or an average length of remaining carbon fibers of about 2 mm to about 6 mm as measured by extracting 100 molded articles having been left at 550° C./1 hr.

The present invention also provides a molded article produced using the composition. The molded article may have a structure in which (B) a carbon fiber and (C) a metallic filler are impregnated in (A) a polyamide resin including an aromatic moiety in the backbone.

In one embodiment, the molded article may be a bracket for protecting LCDs in portable display products.

In one embodiment, the molded article may be produced by melting the (A) polyamide resin including an aromatic moiety in the backbone and the (C) metallic filler; passing the (B) carbon fibers through the melt to impregnate the melt, followed by pelletization; and molding the pellets. In one embodiment, pelletization may be achieved by cutting the carbon fibers into which the melt is impregnated.

In one embodiment, the pellets may have a length of about 8 mm to about 20 mm.

In one embodiment, in the molded article, the carbon fiber having a length of about 0.5 mm to about 6 mm may be present in an amount of about 80 wt % or more, based on the total weight (amount) of carbon fiber in the molded article.

The present invention provides a high-rigidity electromagnetic shielding composition, which can have excellent mechanical strength and conductivity, low surface resistance suitable for EMI shielding, good flowability and/or moldability, no need for post-processing, outstanding economic feasibility and productivity, good dimensional stability and which is capable of replacing existing magnesium materials, and molded articles thereof.

### DETAILED DESCRIPTION OF THE INVENTION

The present invention now will be described more fully hereinafter in the following detailed description of the invention, in which some, but not all embodiments of the invention are described with reference to the accompanying drawings. Indeed, this invention may be embodied in many different forms and should not be construed as limited to the embodiments set forth herein; rather, these embodiments are provided so that this disclosure will satisfy applicable legal requirements.

According to the present invention, a high-rigidity electromagnetic shielding composition includes (A) a polyamide resin including an aromatic moiety; (B) carbon fibers; and (C) a metallic filler.

Each component will now be described in detail.

(A) Polyamide Resin

As the polyamide resin (A), a polyamide resin including an aromatic moiety may be used. Examples of the (A) polyamide resin may include without limitation wholly aromatic polyamides, semi-aromatic polyamides, and mixtures thereof.

In this invention, since the aromatic polyamide contains an aromatic moiety, the aromatic polyamide may impart high rigidity and strength.

The wholly aromatic polyamide may be a polymer of an aromatic diamine and an aromatic dicarboxylic acid.

The semi-aromatic polyamide refers to a polyamide including at least one aromatic unit and non-aromatic unit between the amide bonds. In one embodiment, the semi-aromatic polyamide may be a polymer of an aromatic diamine and an aliphatic dicarboxylic acid.

In one embodiment, the semi-aromatic polyamide may include a polyamide represented by Formula 1:

H—[—NHCH₂—Ar—CH₂NHCO—R—COₙOH [Formula 1]

wherein Ar is an aromatic moiety, R is C₄ to C₂₀ alkylene, and n is an integer ranging from 50 to 500.

In Formula 1, Ar may be a substituted or unsubstituted aromatic group. Unless otherwise indicated, the term “substituted” means that a hydrogen atom of a compound is substituted by a halogen atom (F, Cl, Br, and I), a hydroxyl group, a nitro group, a cyano group, an amino group, an azido group, an amidino group, a hydrazino group, a hydrazono group, a carbonyl group, a carbamyl group, a thiol group, an ester group, a carboxyl group or salt thereof, a sulfonic acid group or salt thereof, a phosphate group or salt thereof, a C₁ to C₂₀ alkyl group, a C₂ to C₂₀ alkenyl group, a C₂ to C₂₀ alkynyl group, a C₁ to C₂₀ alkoxy group, a C₆ to C₃₀ aryl group, a C₆ to C₃₀ aryloxy group, a C₃ to C₃₀ cycloalkyl group, a C₃ to C₃₀ cycloalkenyl group, a C₃ to C₃₀ cycloalkynyl group, or a combination thereof.

There may be at least one, or more, aromatic groups.

As used herein, the term aromatic group and/or aromatic moiety includes C6 to C20 aryl.

Further, R may be a linear or branched C₄ to C₂₀ alkylene group.

In another embodiment, the semi-aromatic polyamide may be a polymer of an aliphatic diamine and an aromatic dicarboxylic acid, as represented by Formula 2:

H—[—NHCH₂—R—CH₂NHCO—Ar—COₙOH [Formula 2]

wherein Ar is an aromatic moiety, R is C₄ to C₂₀ alkylene, and n is an integer ranging from 50 to 500.

In Formula 2, Ar may be a substituted or unsubstituted aromatic group.

There may be at least one or more aromatic groups.

Further, R may be a linear or branched C₁ to C₂₀ alkylene group.

Examples of the aromatic diamine may include without limitation p-xylene diamine, m-xylene diamine, and the like. These may be used alone or in combination of two or more thereof.

Examples of the aromatic dicarboxylic acid may include without limitation phthalic acid, isophthalic acid, terephthalic acid, naphthalene-2,6-dicarboxylic acid, diphenyl 4,4′-dicarboxylic acid, 1,3-phenylenedioxy diacetic acid, and the like. These may be used alone or in combination of two or more thereof.

Examples of the aliphatic diamine may include without limitation 1,2-ethylene diamine, 1,3-propylene diamine, 1,6-hexamethylene diamine, 1,12-dodecylene diamine, piperazine, and the like. These may be used alone or in combination of two or more thereof.

Examples of the aliphatic dicarboxylic acid may include without limitation adipic acid, sebasic acid, succinic acid, glutaric acid, azelaic acid, dodecandioic acid, dimer acid, cyclohexane dicarboxylic acid, and the like. These may be used alone or in combination of two or more thereof.

In one embodiment, the polyamide resin (A) may have a glass transition temperature (Tg) of about 80° C. to about 120° C., for example about 83° C. to about 100° C. When the polyamide resin (A) has a Tg within this range, the composition may have an excellent balance of properties such as flowability and rigidity and low absorption rate may be obtained.

Examples of the polyamide resin (A) include without limitation nylon MXD6, nylon 6T, nylon 9T, nylon 10T, nylon 61/6T, and the like, for example, the polyamide resin (A) can be nylon MXD6. These may be used alone or in combination of two or more thereof.

In another embodiment, the polyamide resin (A) may further include an aliphatic polyamide resin. Examples of the aliphatic polyamide may include without limitation nylon 6, nylon 66, nylon 11, nylon 12, and the like, and combinations thereof.

The composition of the present invention may include the polyamide resin in an amount of about 10 wt % to about 34 wt %, for example about 15 wt % to about 30 wt %, based on the total weight (100 wt %) of the (A)+(B)+(C) components. In some embodiments, the composition may include the polyamide resin in an amount of about 10, 11, 12, 13, 14, 15, 16, 17, 18, 19, 20, 21, 22, 23, 24, 25, 26, 27, 28, 29, 30, 31, 32, 33, or 34 wt %. Further, according to some embodiments of the present invention, the amount of the polyamide resin can be in a range from about any of the foregoing amounts to about any other of the foregoing amounts.

If the amount of (A) polyamide resin is greater than about 34 wt %, modulus and strength can be deteriorated, volume resistance can be increased, and EMI shielding can be deteriorated. If the amount of (A) polyamide resin is less than about 10 wt %, moldability may be deteriorated.

(B) Carbon Fiber

The carbon fibers used in the present invention are well known to those skilled in the art, and may be commercially available or may be produced by conventional methods.

In one embodiment, the carbon fibers may be produced from PAN type and/or pitch type carbon fibers.

The carbon fibers may have an average diameter of about 1 μm to about 30 μm, for example about 3 μm to about 20 μm, and as another example about 5 μm to about 15 μm. When the carbon fibers have an average diameter within this range, good physical properties and conductivity may be obtained.

In one embodiment, the carbon fibers may be subjected to surface treatment.

Further, the carbon fibers may include a bundle of carbon fibers. In one embodiment, the carbon fibers may include long carbon fibers in a bundle form of about 400 TEX to about 3000 TEX may be used. For example, the carbon fibers can include long carbon fibers in a bundle form of about 800 TEX to about 2400 TEX, and as another example about 800 TEX to about 1700 TEX. As used herein, as will be understood by the skilled artisan, the term TEX is a measure of the weight of fiber per unit length, expressed as grams per 1000 meters of roving or yarn. When the carbon fibers have a size within this range, impregnation into the carbon fibers may be smoothly carried out.

The carbon fibers having a bundle form may be impregnated with a melt of the polyamide resin (A) so that the surface of the carbon fibers may be covered with the polyamide resin (A). Then, the carbon fibers, the surface of which is covered with the polyamide resin (A), may be cut to a length of about 8 mm to about 20 mm in a pelletizing process. Since the carbon fibers are cut along the length thereof, the length of the pellets is identical to the length of the cut carbon fibers. That is, pellets having a length of about 8 mm to about 20 mm may contain carbon fibers having a length of about 8 mm to about 20 mm. In some embodiments, the carbon fibers can have a length of about 8, 9, 10, 11, 12, 13, 14, 15, 16, 17, 18, 19, or 20 mm. Further, according to some embodiments of the present invention, the length of the carbon fibers can be in a range from about any of the foregoing amounts to about any other of the foregoing amounts.

Then, the pellets may be processed by a molding process such as injection molding and the like to obtain a molded article. The final molded article may have a structure in which the carbon fibers are dispersed.

In addition, most conventional carbon fibers are cut after molding. In the case where long carbon fibers having a length of about 8 mm to about 20 mm are used, most remaining carbon fibers in the molded article may have a length of about 0.5 mm to about 6 mm. In some embodiments, most remaining carbon fibers in the molded article may have a length of about 0.5, 0.6, 0.7, 0.8, 0.9, 1, 2, 3, 4, 5, or 6 mm. Further, according to some embodiments of the present invention, the length of the remaining carbon fibers in the molded article can be in a range from about any of the foregoing amounts to about any other of the foregoing amounts.

As used herein, the length of the remaining carbon fiber refers to the length of carbon fibers after pelletizing and molding. The term “molding” means typical molding. Generally, the molding is injection molding performed at a temperature of about 280° C. to about 320° C. and a pressure of about 170 Mpa to about 190 Mpa. It should be understood that these molding conditions are provided for simple illustration, and the present invention is not limited thereto.

In contrast, if a molded product is produced using conventional chopped fibers, it can be difficult for the remaining carbon fibers in the molded article to have a length of more than about 0.5 mm, which can cause a difference in physical properties. In some embodiments, in the molded article, the amount of the remaining carbon fibers having a length of about 0.5 mm to about 6 mm may be about 80 wt % or more, for example about 90 wt % or more of the total amount of the carbon fibers in the molded article. Further, the remaining carbon fibers may have an average length of about 2 mm or more, for example about 3 mm or more as obtained measured by extracting 100 molded articles having been left at 550° C. for 1 hour and measuring the length of the carbon fibers in the longitudinal direction.

The composition of the invention can include carbon fiber in an amount of about 65 wt % to about 85 wt %, for example about 65 wt % to about 80 wt %, based on the total weight (100 wt %) of (A)+(B)+(C) components. In some embodiments, the composition can include carbon fiber in an amount of about 65, 66, 67, 68, 69, 70, 71, 72, 73, 74, 75, 76, 77, 78, 79, 80, 81, 82, 83, 84, or 85 wt %. Further, according to some embodiments of the present invention, the amount of the carbon fibers can be in a range from about any of the foregoing amounts to about any other of the foregoing amounts.

If the amount of carbon fibers is less than about 65 wt %, modulus and flexural modulus can be deteriorated, volume resistance and absorption rate can be increased, and EMI shielding can be deteriorated. If the amount of carbon fibers is greater than about 85 wt %, flowability, impact strength and flexural modulus can be decreased.

(C) Metallic Filler

In the present invention, any metallic filler may be used without limitation, so long as the fillers have conductivity. Examples of the metallic fillers (C) may include without limitation aluminum, stainless, iron, chromium, nickel, black nickel, copper, silver, gold, platinum, palladium, tin, cobalt, alloys thereof, and the like. These may be used alone or in combination of two or more thereof. In one embodiment, the metallic filler may be an alloy of iron-chromium-nickel.

In another embodiment, metal oxides or metal carbides such as tin oxide, indium oxide, silicon carbide, zirconium carbide, titanium carbide, and the like, and combinations thereof may also be used as the metallic filler (alone or in combination with the metallic fillers described above).

In a further embodiment, the metallic filler may include a low melting point metal, which includes a main component selected from the group consisting of tin, lead and mixtures thereof, and a subcomponent selected from the group consisting of copper, aluminum, nickel, silver, germanium, indium, zinc and mixtures thereof. The low melting point metal may have a melting point of about 300° C. or less, for example about 275° C. or less, and as another example about 250° C. or less.

In the case of using such a low melting point metal, the network between the fillers may be easily formed and electromagnetic shielding efficiency may be further improved. It is desirable that such a low melting point metal has a solidus temperature (the time where coagulation is completed) lower than a composite process temperature of the polyamide resin (A). If the low melting point metal has a solidus temperature at least about 20° C. lower than the composite process temperature of the polyamide resin (A), the low melting point metal can have merits in terms of composite manufacture and network formation between the fillers. If the low melting point metal has a solidus temperature at least about 100° C. lower than the composite process temperature of the polyamide resin (A), the low melting point metal can have merits in terms of stability. The low melting point metal may have a melting point of about 300° C. or less and a component ratio of tin/copper (about 90 to about 99/about 1 to about 10 weight ratio) and tin/copper/silver (about 90 to about 96/about 3 to about 8/about 1 to about 3 weight ratio).

The metallic filler may be metal powders, metal beads, metal fibers, metal flakes, metal-coated particles, metal-coated fibers, and the like. These may be used alone or in combination of two or more thereof.

In the case of using metallic fillers in the form of metal powders or metal beads, the metallic fillers may have an average particle diameter ranging from about 30 μm to about 300 μm. When the metal powders and/or metal beads have an average particle diameter within this range, feeding may be readily carried out upon extrusion.

In the case of using metallic fillers in the form of metal fibers, the metallic filler may have a length of about 50 nm to about 500 nm and a diameter ranging from 10 μm to about 100 μm. Further, metal fiber having a density of about 0.7 g/ml to about 6.0 g/ml may be used. When the metal fibers have a length, diameter and/or density within these ranges, suitable feeding may be maintained upon extrusion.

In the case of using metallic fillers in the form of metal flake, the metallic fillers may have an average size ranging from about 50 μm to about 500 μm. When the metal flake has an average size within this range, suitable feeding may be maintained upon extrusion.

The metal powders, metal beads, metal fibers, metal flakes, and the like may be comprised of a single metal or an alloy of two or more metals, and may have a multilayer structure.

Metal-coated particles and metal-coated fibers may be prepared by coating a core comprised of one or more resins, ceramics, metals, carbons and the like with metal. For example, metal-coated particles and metal-coated fibers may be prepared by coating resin particulates and/or fibers with a metal, such as nickel, nickel-copper, and the like. The metal coating may be a single layer or multiple layers.

In one embodiment, the metal-coated particles may have an average particle diameter of about 30 μm to about 300 μm. When the metal-coated particles have an average diameter within this range, feeding may be readily carried out upon extrusion.

Further, the metal-coated fibers may have an average diameter ranging from about 10 μm to about 100 μm and a length of about 59 nm to about 500 nm. When the metal-coated fibers have an average diameter and/or length within these ranges, suitable feeding may be maintained upon extrusion.

The composition of the present invention may include the metallic filler (C) in an amount of about 1 wt % to about 20 wt %, for example about 3 wt % to about 15 wt %, based on the total weight (100 wt %) of the (A)+(B)+(C) components. In some embodiments, the composition can include the metallic filler in an amount of about 1, 2, 3, 4, 5, 6, 7, 8, 9, 10, 11, 12, 13, 14, 15, 16, 17, 18, 19, or 20 wt %. Further, according to some embodiments of the present invention, the amount of the metallic filler can be in a range from about any of the foregoing amounts to about any other of the foregoing amounts.

If the amount of metallic filler (C) is less than about 1 wt %, conductivity can be decreased. If the amount of metallic filler (C) is greater than about 20 wt %, flowability, impact strength and flexural modulus can be decreased.

In one embodiment, the weight ratio of the (B) component to the (C) component (B):(C) may range from about 6:about 1 to about 20:about 1. When the weight ratio of the (B) component to the (C) component is within this range, good balance of physical properties can be obtained.

The composition may further include carbon nanotubes. The carbon nanotubes may include single-wall carbon nanotubes, double-wall carbon nanotubes, multi-wall carbon nanotubes, and combinations thereof. In exemplary embodiments, the carbon nanotubes are multi-wall carbon nanotubes. When the composition contains carbon nanotubes, surface resistance can be remarkably reduced and good electromagnetic shielding properties and rigidity can be obtained. The composition of the invention may include carbon nanotubes in an amount of about 0 to about 20 parts by weight, for example about 1 to 15 parts by weight, and as another example about 1 to 10 parts by weight, based on about 100 parts by weight of (A)+(B)+(C). In some embodiments, the composition may include the carbon nanotubes in an amount of 0 (no carbon nanotubes are present), about 0 (carbon nanotubes are present), 1, 2, 3, 4, 5, 6, 7, 8, 9, 10, 11, 12, 13, 14, 15, 16, 17, 18, 19, or 20 parts by weight. Further, according to some embodiments of the present invention, the amount of carbon nanotubes can be in a range from about any of the foregoing amounts to about any other of the foregoing amounts.

When the composition includes carbon nanotubes in an amount within this range, good flowability, rigidity and electromagnetic shielding properties can be obtained.

The composition may further include metal-coated graphite. The metal-coated graphite may have a particle shape, a fiber shape, a flake shape, an amorphous shape, or a combination thereof. When the metal-coated graphite has a fiber shape, the metal-coated graphite may form a network structure together with the carbon fibers.

When the composition contains metal-coated graphite, surface resistance can be greatly reduced, and excellent electromagnetic shielding properties and rigidity may be obtained.

The metal-coated graphite may have an average diameter of about 10 μm to about 200 μm. In the case where the metal-coated graphite is in the form of fibers, the metal-coated graphite may have an average diameter of about 10 μm to about 200 μm, and an average length of about 15 μm to about 100 μm. When the metal-coated graphite fiber have an average diameter and/or average length within these ranges, good electrical conductivity may be obtained and decrease in physical properties by the addition of the metal-coated graphite is minimal.

In one embodiment, any metal having conductivity may be used. Examples of the metals may include without limitation aluminum, stainless steel, iron, chromium, nickel, black nickel, copper, silver, gold, platinum, tin, cobalt, alloys thereof, and the like, and combinations thereof.

The metal coating may be not only a single layer but also multiple layers having two or more layers.

In one embodiment, the metal-coated graphite may be present in an amount of about not more than about 10 parts by weight, for example about 0.1 parts by weight to about 7 parts by weight, based on about 100 parts by weight of (A)+(B)+(C). In some embodiments, the composition may include the metal-coated graphite in an amount of 0 (no metal-coated graphite is present), about 0 (metal-coated graphite is present), 0.1, 0.2, 0.3, 0.4, 0.5, 0.6, 0.7, 0.8, 0.9, 1, 2, 3, 4, 5, 6, 7, 8, 9, or 10 parts by weight. Further, according to some embodiments of the present invention, the amount of metal-coated graphite can be in a range from about any of the foregoing amounts to about any other of the foregoing amounts.

In another embodiment, the metal-coated graphite may be used together with carbon nanotubes. In this embodiment, the metal-coated graphite may be present in an amount of about 0.1 parts by weight to about 3 parts by weight based on about 100 parts by weight of components (A)+(B)+(C). In this embodiment, the composition may include the metal-coated graphite in an amount of about 0.1, 0.2, 0.3, 0.4, 0.5, 0.6, 0.7, 0.8, 0.9, 1, 2, or 3 parts by weight. Further, according to some embodiments of the present invention, the amount of metal-coated graphite can be in a range from about any of the foregoing amounts to about any other of the foregoing amounts. In these embodiments, when the metal-coated graphite is used in an amount within this range, excellent flowability, rigidity and electromagnetic shielding properties and rigidity may be obtained.

Further, the composition of the present invention may include one or more additives such as flame retardants, plasticizers, coupling agents, heat stabilizers, light stabilizers, inorganic fillers, mold release agents, dispersing agent, anti-dripping agents, carbon fillers, weather resistant stabilizers and the like in a conventional amount. They may be used alone or in combination of two or more thereof.

The carbon fillers may include various carbon fillers that are different from the carbon fiber (B). Examples of the carbon fillers may include without limitation graphite, carbon nanotubes, carbon black and the like, and combinations thereof. Metal-coated carbon fillers, for example, metal-coated graphite explained above may also be included.

In some embodiments, the composition may have a tensile strength of about 40 GPa or more as measured in accordance with ASTM D638 using a 3.2 mm thick specimen, a flexural modulus of about 40 GPa or more as measured in accordance with ASTM D790 using a 6.4 mm thick specimen, a shielding effect of about 50 dB or more as measured in accordance with EMI D790 using a 1 mm thick specimen at 1 GHz, a volume resistance of about 0.2 Ω·cm or less as measured in accordance with a 4-point probe method using a 1 mm thick specimen, and/or an average length of remaining carbon fibers of about 2 mm to about 6 mm as measured by extracting 100 molded articles having been left at 550° C./1 hr.

In another embodiment, the composition may have a tensile strength of about 315 MPa to about 420 MPa as measured in accordance with ASTM D638 using a 3.2 mm thick specimen, a flexural modulus of about 40 GPa to about 55 GPa as measured in accordance with ASTM D790 using a 6.4 mm thick specimen, a shielding effect of about 53 dB to about 85 dB as measured in accordance with EMI D790 using a 1 mm thick specimen at 1 GHz, a volume resistance of 0.05 Ω·cm to about 0.18 Ω·cm as measured in accordance with a 4-point-probe method using a 1 mm thick specimen, and/or an average length of remaining carbon fibers of about 3.0 mm to about 6 mm as measured by extracting 100 molded articles having been left at 550° C./1 hr.

The present invention also provides a molded article produced from the composition. In one embodiment, the molded article may have a structure in which (B) carbon fibers and (C) metallic fillers are dispersed in (A) a polyamide resin containing an aromatic moiety in the backbone.

In one embodiment, the molded article may be produced by melting (A) a polyamide resin including an aromatic moiety in the backbone and (C) metallic fillers; passing (B) carbon fibers through the melt to impregnate the melt into the carbon fibers, followed by cutting the carbon fibers to produce pellets; and molding the pellets. In one embodiment, pelletization may be carried out by cutting the carbon fibers into which the melt is impregnated. Melting may be carried out at a temperature capable of melting the polyamide resin. Accordingly, the melt may have the metallic fillers dispersed in the polyamide.

The carbon fiber may comprise a bundle of carbon fibers.

In one embodiment, the (A) polyamide resin including an aromatic moiety in the backbone and the (C) metallic fillers may be introduced into an extruder and melted. Then, the (B) carbon fibers may be provided to the melt for impregnation.

In some exemplary embodiments, the molded article may be produced by introducing the (A) polyamide resin including an aromatic moiety in the backbone and the (C) metallic fillers into an extruder, followed by primary pelletizing to prepare complex resin pellets; melting the complex resin pellets; passing the (B) carbon fibers through the melt to impregnate the melt into the carbon fibers, followed by secondary pelletizing the carbon fibers; and molding the secondary pellets into which the carbon fibers are impregnated.

The impregnated mixture may be extruded into long fibers, which in turn are cut into a regular size for pelletization. In one embodiment, the impregnated mixture may be cut into a length of about 8 mm to about 20 mm, for example about 10 mm to about 15 mm. When the impregnated mixture is cut to a length within this range, the shape of the long carbon fibers may be maintained, which can provide excellent shielding properties and strength.

The prepared pellets may be produced into various forms through injection molding, extrusion molding, casting molding, and the like.

The carbon fibers produced into a bundle shape through such a molding process may be dispersed in a network shape within the final molded article. The network may form multiple contact points, by which the carbon fibers are connected to each other.

The carbon fibers may be partially cut after the molding process. In one embodiment, carbon fibers having a length of about 0.5 mm to about 6 mm may be dispersed in a network shape within the molded article. The carbon fibers having a length of about 0.5 mm to about 6 mm are present in an amount of about 80 wt % or more, for example about 90 wt % or more of the total carbon fibers. Further, the molded article may have an average length of remaining carbon fibers of about 2 mm or more, as measured by extracting 100 molded articles having been left at 550° C. for 1 hour.

In one embodiment, since the molded article may have excellent electromagnetic shielding properties, conductivity, mechanical physical properties and moldability, the molded article may be employed in a bracket for protecting LCDs for portable display products.

Hereinafter, the constitution and functions of the present invention will be explained in more detail with reference to the following examples. It should be understood that these examples are provided for illustration only and are not to be in any way construed as limiting the present invention. Descriptions of details apparent to those skilled in the art will be omitted herein.

### EXAMPLES

Details of components used in Examples and Comparative Examples are as follows.

(A) Polyamide resin: Toyobo T-600, which is Nylon-MXD6 produced by Toyobo Co., Ltd., is used.

(A′) Polyamide resin: PA 11 produced by ARKEMA Inc. is used.

(B) Carbon fiber: Toray TORAYCA T700S 50C, 1650TEX produced by Toray Industries, Inc. is used.

(B′) Carbon fiber: Chopped carbon fiber having an average diameter of 7 μm and a length of 6 mm produced by Zoltek Co., Ltd. is used.

(C) Metallic filler

(C1) Micro stainless steel fiber: MSF 150 (Metal short fiber including Fe—Cr—Ni in a weight ratio of 65-15-10) produced by Mirae Corporation is used.

(C2) Metal powder having a low melting point of 300° C. or less: 97C (Powder type tin-copper alloy, 97% Sn, 2.5% Cu) available from Warton Metals Limited is used.

(D) Metal-coated graphite: 2805 (Ni: 75 wt %, graphite: 25 wt %) as a Ni-coated graphite produced by Sulzer Co., Ltd., is used.

(E) Carbon Nano Tube: NC7000 (multiwall CNT) available from Nanocyl S.A., is used.

### Examples 1 to 8

A polyamide resin, a metallic filler, and other additives listed in Table 1 are mixed in a typical mixer and extruded using a biaxial extruder having L/D=35, φ=45 mm to prepare extrudates in the form of pellets. The pellets are melted using a long axis extruder. Then, carbon fibers (B) are impregnated by a pultrusion method and then cut into long pellets having a length of 12 mm. Specimens for evaluating applicability such as physical properties at an injection temperature of 270° C. and EMI resistance are prepared by injection molding for preparation of long fibers. These specimens are left at 23° C. and 50% relative humidity (RH) for 48 hours and then physical properties are measured as follows. Results are shown in Table 1.

Evaluation of Physical Properties:

(1) Tensile strength: Tensile strength is evaluated in accordance with ASTM D638 at 5 mm/min. Unit of tensile strength is represented by MPa.

(2) Flexural modulus: Flexural strength is evaluated in accordance with ASTM D790 at 1.27 mm/min. Unit of flexural modulus is represented by GPa.

(3) EMI shielding (dB): The samples are left at 23° C. and 50% RH for 48 hours and then physical properties of the samples are as measured in accordance with EMI D790 using a 1 mm thick specimen (6×6) at 1 GHz.

(4) Volume resistance: Volume resistance is measured using a 4-point probe method (Ω·cm).

(5) Length (mm) of remaining carbon fibers after ignition loss: The length of remaining carbon fibers is measured by extracting 100 molded articles having been left at 550° C. for 1 hour and then measuring the length of the remaining carbon fibers in the longitudinal direction to obtain arithmetic mean values.

### Comparative Examples 1 to 5

Comparative Examples 1 to 3 are prepared in the same manner as in Example 1 except for using the compositions listed in Table 2.

Comparative Example 4 is prepared in the same manner as in Example 1 except that carbon fibers are impregnated by a pultrusion method and then cut into 6 mm length pellets.

Comparative Example 5 is prepared in the same manner as in Example 1 except that a polyamide resin, a chopped carbon fiber (B′) and a metallic filler are mixed in an amount shown in Table 1 in a typical mixer and extruded using a biaxial extruder having L/D=35, φ=45 mm to prepare extrudates in the form of pellets, and then the pellets are subjected to injection molding to produce specimens for evaluating applicability such as physical properties at an injection temperature of 270° C. and EMI resistance.

TABLE 1

| | | Example | | | | | | | |
|---|---|---|---|---|---|---|---|---|---|
| | | 1 | 2 | 3 | 4 | 5 | 6 | 7 | 8 |
| (A) PA | | 30 | 25 | 30 | 20 | 15 | 20 | 20 | 20 |
| (A′) PA | | — | — | — | — | — | — | — | — |
| (B) Carbon fiber | | 65 | 65 | 65 | 75 | 80 | 75 | 75 | 75 |
| (B^{′}) Carbon fiber | | — | — | — | — | — | — | — | — |
| (chopped) | | | | | | | | | |
| (C) Metallic | C1 | 5 | 10 | — | 5 | 5 | 5 | 5 | 5 |
| filler | C2 | — | — | 5 | — | — | — | — | — |

| | | | | | | | | |
|---|---|---|---|---|---|---|---|---|
| (D) Metal-coated | — | — | — | — | — | 3 | — | 3 |
| graphite | | | | | | | | |
| (E) CNT | — | — | — | — | — | — | 1 | 1 |
| Length of pellet (mm) | 12 | 12 | 12 | 12 | 12 | 12 | 12 | 12 |
| Tensile strength | 318 | 320 | 319 | 343 | 381 | 352 | 345 | 352 |
| Flexural modulus | 45 | 42 | 41 | 43 | 41 | 44 | 43 | 44 |
| EMI shielding (dB) | 53 | 59 | 54 | 65 | 71 | 67 | 66 | 68 |
| Resistance (Ω · cm) | 0.15 | 0.12 | 0.17 | 0.16 | 0.14 | 0.12 | 0.12 | 0.10 |
| Specific gravity | 1.48 | 1.48 | 1.48 | 1.49 | 1.49 | 1.50 | 1.49 | 1.50 |
| Length of remaining | 3.4 | 3.3 | 3.1 | 3.6 | 3.5 | 3.5 | 3.6 | 3.4 |
| carbon fiber after | | | | | | | | |
| ignition loss (mm) | | | | | | | | |

TABLE 2

| | | Comparative Example | | | | |
|---|---|---|---|---|---|---|
| | | 1 | 2 | 3 | 4 | 5 |
| (A) PA | | 35 | — | 55 | 30 | 30 |
| (A′) PA | | — | 30 | — | — | — |
| (B) Carbon fiber | | 65 | 65 | 40 | 65 | — |
| (B^{′}) Carbon fiber | | — | — | — | — | 65 |
| (chopped) | | | | | | |
| (C) Metallic | C1 | — | 5 | 5 | 5 | 5 |
| filler | C2 | — | — | — | — | — |

| | | | | | |
|---|---|---|---|---|---|
| (D) Metal-coated | — | — | — | — | — |
| graphite | | | | | |
| (E) CNT | — | — | — | — | — |
| Length of pellet (mm) | 12 | 12 | 12 | 6 | 6 |
| Tensile strength | 319 | 290 | 270 | 291 | 280 |
| Flexural modulus | 47 | 35 | 31 | 35 | 33 |
| EMI shielding (dB) | 54 | 51 | 38 | 41 | 35 |
| Resistance (Ω · cm) | 0.31 | 0.14 | 0.20 | 0.25 | 0.23 |
| Specific gravity | 1.48 | 1.43 | 1.47 | 1.48 | 1.47 |
| Length of remaining | 3.3 | 3.3 | 3.2 | 1.4 | 0.8 |
| carbon fiber after | | | | | |
| ignition loss (mm) | | | | | |

As shown in Table 1, in Examples 1, 4 and 5, it can be seen that the use of a high content of carbon fibers provided a flexural modulus of 40 GPa or more and an EMI shielding effect of 50 dB or more, and the flexural modulus and EMI shielding effect increased with increasing amount of the carbon fibers. It can be seen that the flexural modulus and EMI shielding effect of Examples 1, 4 and 5 are much higher than those of Comparative Example 3 in which the amount of carbon fiber is smaller than in Examples 1, 4 and 5. Further, as in Comparative Example 2, when an aromatic polyamide is not used, significantly reduced tensile strength and modulus are obtained.

In Examples 1 to 8, since the metallic fillers are used, high modulus and high EMI shielding effect and a low volume resistance of 0.2 Ω·cm or less are obtained. In contrast, in Comparative Example 1 which did not include the metallic fillers, volume resistance is high although modulus and EMI shielding effect are similar.

In Examples 1 to 5 in which long fiber reinforced thermoplastic resins having a pellet length of 12 mm extruded by pultrusion are used, the resins exhibit better properties in terms of modulus, EMI shielding effect and resistance than those of Comparative Example 4 in which 6 mm carbon fibers extruded in the same manner are used. Specifically, in Comparative Example 4, the length of the remaining carbon fibers (ash) after ignition loss is remarkably shortened, causing huge differences in electrical resistance and EMI shielding properties where networking in extrudate is important. It can also seen that Comparative Example 5 in which general chopped 6 mm length carbon fibers are used exhibited remarkably low properties in terms of modulus, EMI shielding properties and resistance.

Many modifications and other embodiments of the invention will come to mind to one skilled in the art to which this invention pertains having the benefit of the teachings presented in the foregoing description. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

That which is claimed is:

1. A high-rigidity electromagnetic shielding composition, comprising:
(A) about 10 wt % to about 34 wt % of a polyamide resin including an aromatic moiety in the backbone;
(B) about 65 wt % to about 85 wt % of carbon fibers; and
(C) about 1 wt % to about 20 wt % of a metallic filler.

2. The high-rigidity electromagnetic shielding composition according to claim 1, wherein the (A) polyamide resin comprises wholly aromatic polyamide, semi-aromatic polyamide, or a combination thereof.

3. The high-rigidity electromagnetic shielding composition according to claim 2, wherein the (A) polyamide resin comprises a semi-aromatic polyamide, and wherein the semi-aromatic polyamide is a polymer of an aromatic diamine and an aliphatic dicarboxylic acid.

4. The high-rigidity electromagnetic shielding composition according to claim 3, wherein the semi-aromatic polyamide is represented by Formula 1:
H—[—NHCH₂—Ar—CH₂NHCO—R—COₙOH
wherein Ar is an aromatic moiety, R is C_{4 to 20} alkylene, and n is an integer ranging from 50 to 500.

5. The high-rigidity electromagnetic shielding composition according to claim 1, wherein the (B) carbon fibers comprises a bundle of carbon fibers.

6. The high-rigidity electromagnetic shielding composition according to claim 1, wherein the (C) metallic filler comprises metal powders, metal beads, metal fibers, metal flakes, metal-coated particles, metal-coated fibers, or a combination thereof.

7. The high-rigidity electromagnetic shielding composition according to claim 1, wherein the (C) metallic filler comprises aluminum, stainless, iron, chromium, nickel, black nickel, copper, silver, gold, platinum, palladium, tin, cobalt, an alloy thereof, or a combination thereof.

8. The high-rigidity electromagnetic shielding composition according to claim 1, further comprising carbon nanotubes in an amount of greater than 0 parts by weight to about 20 parts by weight based on about 100 parts by weight of (A)+(B)+(C).

9. The high-rigidity electromagnetic shielding composition according to claim 8, further comprising metal-coated graphite.

10. The high-rigidity electromagnetic shielding composition according to claim 9, wherein the metal-coated graphite has a particle shape, a fiber shape, a flake shape, an amorphous shape, or a combination thereof.

11. The high-rigidity electromagnetic shielding composition according to claim 10, wherein the metal-coated graphite has an average particle diameter of about 10 μm to about 200 μm.

12. The high-rigidity electromagnetic shielding composition according to claim 9, wherein the metal comprises aluminum, stainless, iron, chromium, nickel, black nickel, copper, silver, gold, platinum, palladium, tin, cobalt, an alloy thereof, or a combination thereof.

13. The high-rigidity electromagnetic shielding composition according to claim 1, further comprising an additive comprising a flame retardant, plasticizer, coupling agent, heat stabilizer, light stabilizer, inorganic filler, mold release agent, dispersing agent, anti-dropping agent, weather proof stabilizer, or a combination thereof.

14. The high-rigidity electromagnetic shielding composition according to claim 1, wherein the composition has a tensile strength of about 40 GPa or more as measured in accordance with ASTM D638 using a 3.2 mm thick specimen, a flexural modulus of about 40 GPa or more as measured in accordance with ASTM D790 using a 6.4 mm thick specimen, a shielding effect of about 50 dB or more as measured in accordance with EMI D790 using a 1 mm thick specimen at 1GHz, a volume resistance of about 0.2 Ω·cm or less as measured in accordance with a 4-point probe method using a 1 mm thick specimen, and an average length of remaining carbon fibers of about 2 mm to about 6 mm as measured by extracting 100 molded articles having been left at 550° C. for 1 hour.

15. A molded article produced from the composition according to claim 1 and having a structure in which the (B) carbon fibers and the (C) metallic filler are dispersed in the (A) polyamide resin including an aromatic moiety in the backbone.

16. The molded article of claim 15, wherein the molded article is a bracket for protecting LCDs in portable display products.

17. The molded article of claim 15, wherein the molded article is produced by melting the (A) polyamide resin including an aromatic moiety in the backbone and the (C) metallic filler; passing the (B) carbon fibers through the melt to impregnate the melt into the carbon fibers, followed by cutting the carbon fibers to produce pellets; and molding the pellets.

18. The molded article of claim 17, wherein the pellets have a length of about 8 mm to about 20 mm.

19. The molded article of claim 15, wherein carbon fibers having a remaining carbon fiber length of about 0.5 mm to about 6 mm are present in an amount of about 80 wt % or more in the molded article, based on the total amount of carbon fibers.
